(19) United States
(12) Patent Application Publication
(10) Pub. No.: US 2018/0113178 A1
(43) Pub. Date: Apr. 26, 2018

(54) Arrangement and method for the touchless operation of an apparatus of measuring technology with an input and output unit

(71) Applicant: VEGA GRIESHABER KG, Wolfach (DE)

(72) Inventor: Juergen Lienhard, Fischerbach (DE)

(21) Appl. No.: 15/697,041

(22) Filed: Sep. 6, 2017

(30) Foreign Application Priority Data
Oct. 24, 2016 (EP) 16 195383.1

(51) Int. Cl. G01R 33/00; G06F 3/0354

(52) U.S. Cl. CPC G01R 33/0047; G01R 33/0005; G06F 2203/04101; G06F 3/03545; G01R 33/0011

(57) ABSTRACT

The invention is an arrangement for the touchless operation of an apparatus of measuring technology with an input and output unit which comprises at least
a control unit
a display unit coupled to the control unit, and
an input unit coupled to the control unit, with the input device comprising at least one magnetic field sensor with a three-dimensional magnetic field detection and a magnetic control element cooperating with the magnetic field sensor.

### CROSS REFERENCE TO RELATED APPLICATIONS

This patent application claims priority to European Patent Application 16195383.1, filed on Oct. 24, 2016.

### STATEMENT REGARDING FEDERALLY SPONSORED RESEARCH OR DEVELOPMENT

No federal government funds were used in researching or developing this invention.

### NAMES OF PARTIES TO A JOINT RESEARCH AGREEMENT

Not applicable.

### SEQUENCE LISTING INCLUDED AND INCORPORATED BY REFERENCE HEREIN

Not applicable.

### BACKGROUND

### Field of the Invention

The invention is an arrangement and method for the touchless operation of an apparatus of measuring technology with an input and output unit.

### Background of the Invention

The present invention relates to an arrangement for the touchless operation of an apparatus of measuring technology with an input and output unit according to the preamble of claim 1 as well as a method for operating an input and output unit of an apparatus of measuring technology according to claim 9.

Arrangements for the touchless operation of an apparatus of measuring technology with an input and output unit are known from prior art, for example for field devices, and are used for the fill level, pressure, and limit measurement in environments with elevated requirements set for the protection class of the device, among other things.

Such field devices with input and output units are known from prior art, for example from DE 37 34 494, which describes a control unit protected from explosion, in which a group of data input/scanning sites is allocated to a group of sensors that can be magnetically operated and is aligned to these scanning sites. In this arrangement of prior art one magnetically operated sensor is respectively allocated to each input key and placed immediately underneath it. When it is now necessary to place an input to the control unit arranged in a casing protected from explosion this can occur via a permanent magnet, by which the magnetically operated sensors can be activated.

The magnetic field sensors typically used in prior art, which usually are formed as reed-contacts or Hall sensors, only allow a detection of a magnetic field above or below a threshold, but not any detection of the orientation and/or a distribution of the field strength in the three-dimensional space. This way here only a yes/no or 0/1 decision is possible via such sensors, which considerably limits the flexibility and range of application of such input and output units.

In these arrangements of prior art it is considered disadvantageous that only the operation of one key is possible and the input is therefore very inflexible.

Alternative options for operating input units of field devices of prior art are for example capacitive inputs, as used for example in modern smartphones and tablets, or the scanning of a field based on infrared radiation. Capacitive inputs are however very limited with regards to the distance such operation can occur, and the scanning of fields based on infrared radiation in embedded systems as used typically in field devices is relatively expensive. Both systems are therefore not useful or practical only to a limited extent. Furthermore, systems operating with infrared radiation are very susceptible to errors due to soiling.

The objective of the present invention is to improve an arrangement for the touchless operation of an apparatus of measuring technology with an input and output unit such that the operation is possible in a more flexible and simultaneously intuitive fashion. Further, the objective of the present invention comprises to provide a method for operating such an input and output unit.

### BRIEF SUMMARY OF THE INVENTION

In a preferred embodiment, an arrangement for the touchless operation of an apparatus of measuring technology (1) with an input and output unit (5), which comprises at least

a control unit (7),
a display unit (9) coupled to the control unit (7), and
an input unit (11) coupled to the control unit (7),
characterized in that the input unit (11) comprises at least one magnetic field sensor (13) with a three-dimensional magnetic field detection and a magnetic control element (15) cooperating with the magnetic field sensor (13).

In another preferred embodiment, the arrangement as described herein, characterized in that the magnetic field sensor (13) is embodied as a three-axis magnetometer.

In another preferred embodiment, the arrangement as described herein, characterized in that the magnetic field sensor (13) and the display unit (9) are arranged in a casing protected from dust and/or water-tight and/or protected from explosion.

In another preferred embodiment, the arrangement as described herein, characterized in that the arrangement comprises a detection of the control element (71).

In another preferred embodiment, the arrangement as described herein, characterized in that the detection of the control element (71) is integrated in the control unit (7), which detects the presence of a user element (15) by evaluating signals of the magnetic field sensor (13).

In another preferred embodiment, the arrangement as described herein, characterized in that the control element (15) shows the form of a pen.

In another preferred embodiment, the arrangement as described herein, characterized in that the control element (15) comprises a permanent magnet (17) or an electromagnet (19) or a combination thereof.

In another preferred embodiment, the arrangement as described herein, characterized in that the control element (15) shows at a distance of 1 cm in the axial direction a flow density from 0.025 mT to 50 mT, preferably at least 0.1 mT.

In another preferred embodiment, the arrangement as described herein, characterized in that the control unit (7) is embodied such that any presence of the control element (15) inside a predetermined area or a brief change of a strength and/or polarity of a magnetic field detected at the magnetic field sensor (13) is interpreted as the confirmation of an input.

In an alternate preferred embodiment, a method for operating an input and output unit (5) of an apparatus of measuring technology, with the input and output unit (5) comprising at least one control unit (7), a display unit (9) coupled to the control unit (7), and an input unit (11) coupled to the control unit (7), with further the input unit (11) comprising at least one magnetic field sensor (13) with three-dimensional magnetic field detection and a magnetic control element (15) cooperating with the magnetic field sensor (13), with the method detecting a position and/or motion of the control element (15) in a detection range of the magnetic field sensor (13) and converting it into a corresponding continuous motion and/or position of a graphic representation (25) of the control element (15) on the display unit (9).

In another preferred embodiment, the method as described herein, in which the input and output unit (5) is transferred from an operating mode into a sleep mode after a predetermined period without any input or a user command.

In another preferred embodiment, the method as described herein, in which the input and output unit (5), when the control element (15) is moved into a predetermined detection range, is transferred from a sleep mode into an operating mode.

In another preferred embodiment, the method as described herein, in which in the operating mode any presence of the control element (15) and/or the graphic representation (25) for a predetermined time at a position inside the detection area is interpreted as a confirmation of an input.

In another preferred embodiment, the method as described herein, in which the duration present is displayed graphically.

In another preferred embodiment, the method as described herein, in which in the operating mode a brief change of the magnetic field detected at the magnetic field sensor (13), particularly a field strength and/or polarity, is interpreted as the confirmation of an input.

In another preferred embodiment, the method as described herein, in which a scanning rate of the magnetic field sensor (13) is adjustable.

In an alternate preferred embodiment, an apparatus of measuring technology for the touchless operation as described herein, which is operated according to a method also described herein.

### BRIEF DESCRIPTION OF THE DRAWINGS

FIG. 1 is a line drawing evidencing a schematic illustration of an apparatus of measuring technology according to the present invention.

FIG. 2 is a line drawing evidencing the display unit of the apparatus of FIG. 1 in an enlarged illustration.

### DETAILED DESCRIPTION OF THE INVENTION

The arrangement according to the invention for the touchless operation of an apparatus of measuring technology, particularly a field device of the fill level, pressure, or limit measuring technology, comprises an input and output unit, which includes at least a control unit, a display unit coupled to the control unit, and an input device coupled to the control unit, with the input unit comprising at least one magnetic field sensor with a three-dimensional magnetic field detection and a magnetic control element cooperating with the magnetic field sensor.

By the use of at least one magnetic field sensor with a three-dimensional magnetic field detection as well as a magnetic control element cooperating with the magnetic field sensor, here a detection of the magnetic field is possible in all spatial directions, so that with the help of the magnetic control element the operation of the device can occur similar to the operation of a computer with a mouse or a track pad, however in a touchless fashion. This way, graphic representation of a position of the magnetic control element can be realized on the display unit in the form of a cursor or mouse indicator similar to the operation of a computer and thus a very intuitive input can be realized.

A particularly beneficial realization with simultaneously excellent features with regards to spatial resolution and power consumption is possible when using a compass sensor, for example a magnetometer with magneto-resistive sensors for a three-axis magnetic field detection. Such compass sensors are used in mass applications, such as smartphones, tablets and the like and thus they are not very costly. Further, such sensors are available with a very high degree of miniaturization, a high resolution of the measurements in all spatial directions, a wide and adjustable measuring range, as well as a low need for energy.

The present arrangement is particularly suitable for the use in dust-protected and/or water-tight and/or explosion-protected casings so that the use of the arrangement is possible in environments that must be protected from dust and/or water and/or explosion. Here it is particularly possible that the magnetic field sensor and the display unit are arranged in a casing of the appropriate protection class and that a touchless operation is possible with the help of the magnetic control element from outside the casing.

The arrangement can further comprise a detection of presence of the control element, so that the input and output unit, and particularly the display unit, are only transferred into an operating mode with elevated energy use when the presence of the control element is detected in a detection range of the magnetic field sensor. For example, in a sleep mode, the scanning rate of the magnetic field sensor can be drastically reduced and the display unit deactivated. When the magnetic control element is moved into the detection range of the magnetic field sensor and accordingly the presence of the magnetic control element in said detection range is noticed, the field device can be switched into the operating mode with elevated scanning rate and activated display unit.

An intuitive, targeted, and precise operation can be achieved such that the control element shows the form of a pen.

The magnetic features of the control element can for example be yielded by a permanent magnet, an electromagnet, or a combination of a permanent magnet and an electromagnet.

With the help of a permanent magnet, a very simply designed and robust control unit can be provided, while with the help of an electromagnet or a combination of an electromagnet with a permanent magnet an active input is possible, for example by modulating the field strength, by changing the polarization, or other suitable influences of the magnetic field. The permanent magnet, the electromagnet or the combination of the permanent and the electric magnet comprises here preferably at a distance of 1 cm a flow density from 0.025 mT to 50 mT, preferably of at least 0.1 mT.

This way, reliable operation of the input unit is ensured, even at a distance of several centimeters and through casings of appropriate protective classes, which typically show thick glass panes for protection from explosion.

In order to ensure the optimal use of the arrangement it may be beneficial if it shows a module or functionality for calibration. This way, disturbing magnetic fields, for example the earth's magnetic field but also disturbing influences of other magnetic components, can be compensated.

Advantageously the control unit of the present arrangement is designed such that any presence of the control element inside the predetermined area or a brief change of the strength and/or polarity of a magnetic field detected at the magnetic field sensor is interpreted as an input performed.

Any presence of the control element within a predetermined range can be detected, for example, when the graphic representation of the control element on the display is located inside a field graphically indicated there and the control element is then moved no longer or only to a minor extent for a predetermined period. Alternatively, in case of an appropriate placement of the mouse cursor the change of the strength of the magnetic field can be evaluated by a brief approach of the control element in the direction of the magnetic field sensor as the confirmation of an input. When an electromagnet is used, any change of the strength of the magnetic field by a brief increase of the current flowing or a change in polarity of the electromagnet by reversing polarity can be used for confirming an input.

The same applies for a combination of a permanent magnet and an electromagnet.

In a method for operating an input and output unit of an apparatus of measuring technology, in which the input and output unit comprises at least a control unit, a display unit coupled to a control unit, and an input unit coupled to the control unit, and with further the input unit comprising at least one magnetic field sensor with a three-dimensional magnetic field detection and a magnetic control element cooperating with the magnetic field sensor, a positioning and/or motion of the control element is detected in a detection range of the magnetic field sensor and converted into a corresponding continuous motion and/or position of a graphic representation of the control element on the display unit.

By a method in which a positioning and/or motion of the control unit is detected in a detection area of the magnetic field sensor and is converted into a corresponding continuous motion and/or position of a graphic representation of the control element, particularly a mouse indicator or cursor, an intuitive flexible operation of a respective apparatus of measuring technology is possible, particularly a field device for fill level, pressure, or limit measurement. In particular, it is possible thereby that an adaption is possible for operating different menu levels with various input masks. An appropriate method further allows not only to perform an adaption to the input masks but also more complex input variants, for example the detection of manuscript, or the detection of simple gestures, which are performed with the control element.

An energy saving effect can be achieved when the input and output unit is converted after a predetermined period without any input or user command from an operating mode into a sleep mode. In a sleep mode, for example a scanning frequency of the magnetic field sensor can be reduced and/or the display unit can be deactivated, for example a pixel-based display.

If then the control element is returned into the predetermined detection range of the magnetic field sensor the input and output unit can be converted back out of the sleep mode into an operating mode, for example with an activated display unit and an elevated scanning rate of the magnetic field sensor.

In the present method the input and/or an activation of an input can occur such that the presence of the control element and/or the graphic representation thereof for a predetermined period at a position inside the detection range can be interpreted as confirmation. For example, an input corresponding to a key stroke can be implemented such that an activation of a key displayed on the display unit is assumed when the cursor remains for a predetermined period within the displayed key field.

Such an input can be designed in an intuitive fashion for the user such that the period of the cursor present inside the predetermined area is displayed in a graphic fashion. For example, a selected key can be shown in a colored fashion, depending on the period of the cursor present on said key, or filled like a bar graph. Alternatively, in the operating mode a brief change of the magnetic field detected at the magnetic field sensor, particularly a change of a field strength and/or a polarity of the magnetic field, can be interpreted as a confirmation of an input.

For different types of input, for example the pushing of displayed keys on one side or a manuscript detection on the other side, it may be beneficial for the scanning range of the magnetic field sensor to be adjustable.

Also, according to the invention, an apparatus of measuring technology comprises an arrangement for the touchless operation according to any of claims 1 to 8, which is operated according to any of claims 9 to 15.

### DETAILED DESCRIPTION OF THE FIGURES

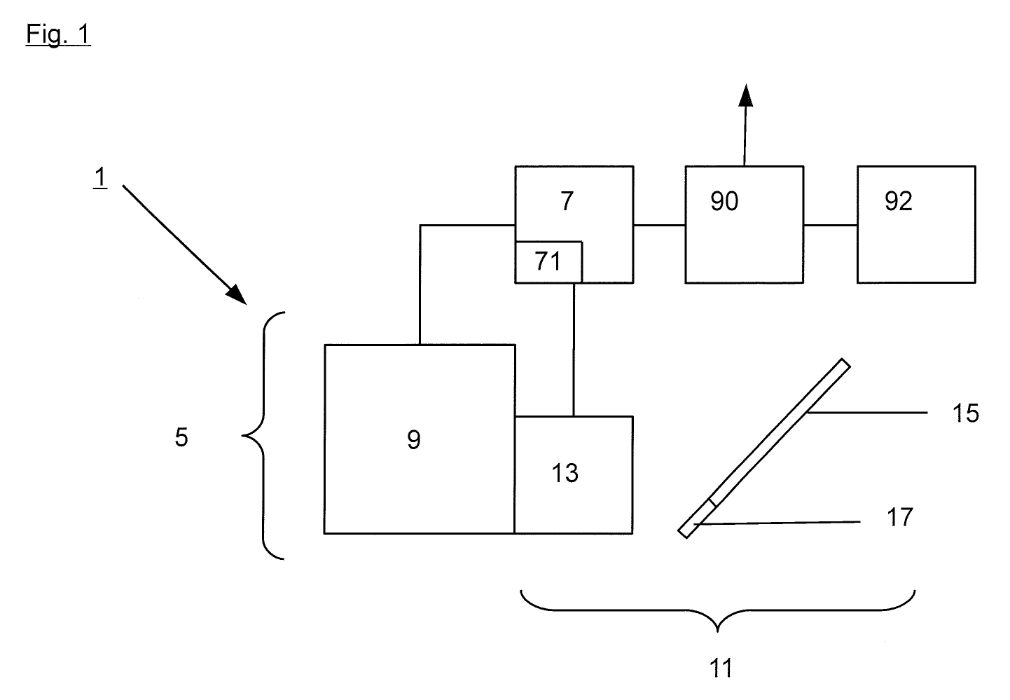

FIG. 1 shows a schematic illustration of an apparatus of measuring technology 1, which for example may represent a fill level meter, a manometer, or a limit measuring device. The apparatus of measuring technology 1 comprises an input and output unit 5, which cooperates with a sensor electronic 90 and a sensor 92 connected thereto. The sensor 92 is here connected to the device electronic 90, which may be connected for example to a control panel. In order to configure the device electronic 90 and for the output of measurements on a display unit 9 the device electronic 90 is further connected to an input and output unit 5.

The input and output unit 5 is essentially formed from a control unit 7, a display unit coupled to the control unit 7, as well as an input unit 11 coupled also to the control unit 7. The input unit 11 is embodied in two parts in the present exemplary embodiment, with one magnetic field sensor 13 with a three-dimensional magnetic field detection being connected to the control unit 7. A control element 15, which in the present case is embodied like a pen and equipped with a permanent magnet 17, is embodied as a separate unit and serves for the touchless operation of the input and output unit 5, and thus also the apparatus of measuring technology 1.

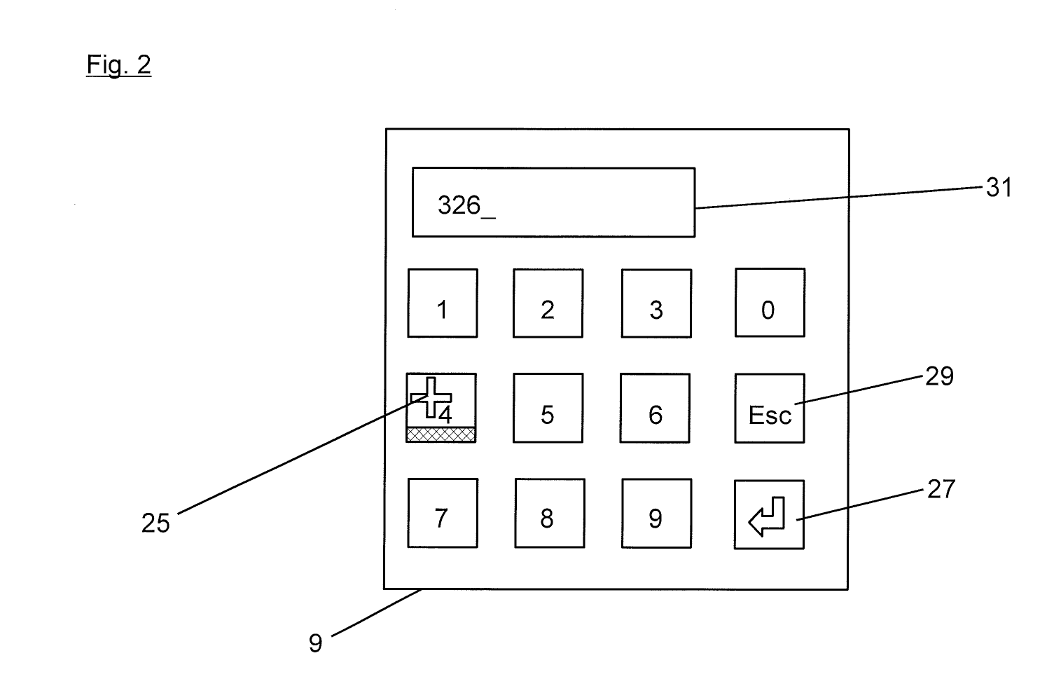

FIG. 2 shows an enlarged illustration of the display unit 9 of the apparatus of measuring technology 1 of FIG. 1. FIG. 2 shows a potential embodiment of a display that can be shown on the display unit 9. In the example shown in FIG. 2 a numeric block with numbers from 0 to 9, a confirmation key 27, as well as a cancel key 29 are shown, and additionally an input field 31 for displaying a sequence of numbers entered.

In the area of the displayed key with the number “4” further a graphic representation 25 of the control element 15 is shown, in the present case as a cross. An input is triggered by the graphic representation 25 remaining in the area of the displayed key. This is graphically characterized by a gradual filling of the displayed numeric field with a cross-wise hatching. When the numeric field is completely filled, this is considered an entry made and the respective number is displayed in the input field 31 shown above.

In case of an appropriately high resolution of the magnetic field sensor further a detection of manuscript and/or gestures can be implemented during the input with the magnetic operating element 15. This represents an additional or alternative input method. Operation can also occur by an appropriately strongly magnetized control element 15 or an appropriately strong electromagnet 19 arranged in the control element 15 also through, for example thick glass panes or casing parts, unless they are magnetic as well. This way, all components of the apparatus of measuring technology 1 can be arranged in a casing protected from dust, water, or explosion and thus the respective device can be used in the environments of devices with respective protective classes.

### LIST OF REFERENCE NUMBERS

1 Apparatus of measuring technology
5 Input and output unit
7 Control unit
9 Display unit
11 Input unit
13 Magnetic field sensor
15 Control elements
17 Permanent magnet
19 Electromagnet
25 Representation
27 Input key
29 Cancellation key
31 Input field
71 Detection of control element
90 Device electronic
92 Sensor

The references recited herein are incorporated herein in their entirety, particularly as they relate to teaching the level of ordinary skill in this art and for any disclosure necessary for the commoner understanding of the subject matter of the claimed invention. It will be clear to a person of ordinary skill in the art that the above embodiments may be altered or that insubstantial changes may be made without departing from the scope of the invention. Accordingly, the scope of the invention is determined by the scope of the following claims and their equitable equivalents.

We claim:

1. An arrangement for the touchless operation of an apparatus of measuring technology with an input and output unit, which comprises at least
a control unit,
a display unit coupled to the control unit, and
an input unit coupled to the control unit,
wherein the input unit comprises at least one magnetic field sensor with a three-dimensional magnetic field detection and a magnetic control element cooperating with the magnetic field sensor.

2. The arrangement according to claim 1, wherein the magnetic field sensor is embodied as a three-axis magnetometer.

3. The arrangement according to claim 2, wherein the magnetic field sensor and the display unit are arranged in a casing protected from dust and/or water-tight and/or protected from explosion.

4. The arrangement according to claim 1, wherein the arrangement comprises a detection of the control element.

5. The arrangement according to claim 4, wherein the detection of the control element is integrated in the control unit, which detects the presence of a user element by evaluating signals of the magnetic field sensor.

6. The arrangement according to claim 1, wherein the control element shows the form of a pen.

7. The arrangement according to claim 6, wherein the control element comprises a permanent magnet or an electromagnet or a combination thereof.

8. The arrangement according to claim 7, wherein the control element shows at a distance of 1 cm in the axial direction a flow density from 0.025 mT to 50 mT, preferably at least 0.1 mT.

9. The arrangement according to claim 1, wherein the control unit is embodied such that any presence of the control element (15) inside a predetermined area or a brief change of a strength or polarity of a magnetic field detected at the magnetic field sensor is interpreted as the confirmation of an input.

10. A method for operating an input and output unit of an apparatus of measuring technology, with the input and output unit comprising at least one control unit, a display unit coupled to the control unit, and an input unit coupled to the control unit, with further the input unit comprising at least one magnetic field sensor with three-dimensional magnetic field detection and a magnetic control element cooperating with the magnetic field sensor (13), with the method detecting a position and motion of the control element in a detection range of the magnetic field sensor and converting it into a corresponding continuous motion and/or position of a graphic representation of the control element on the display unit.

11. A method according to claim 10, in which the input and output unit is transferred from an operating mode into a sleep mode after a predetermined period without any input or a user command.

12. A method according to claim 10, in which the input and output unit, when the control element is moved into a predetermined detection range, is transferred from a sleep mode into an operating mode.

13. A method according to claim 10, in which in the operating mode any presence of the control element and the graphic representation for a predetermined time at a position inside the detection area is interpreted as a confirmation of an input.

14. A method according to claim 13, in which the duration present is displayed graphically.

15. A method according to claim 10, in which in the operating mode a brief change of the magnetic field detected at the magnetic field sensor, particularly a field strength and polarity, is interpreted as the confirmation of an input.

16. A method according to claim 10, in which a scanning rate of the magnetic field sensor is adjustable.

17. An apparatus of measuring technology for the touchless operation according to claim 1, which is operated according to a method according to claim 10.
